(19) United States
(12) Patent Application Publication
(10) Pub. No.: US 2021/0380400 A1
(43) Pub. Date: Dec. 9, 2021

(54) Micro-Electromechanical Systems Including Printed Circuit Boards and Pre-Fabricated Polymer Films

(71) Applicant: University of Utah Research Foundation, Salt Lake City, UT (US)

(72) Inventors: Moritz Leber, Salt Lake City, UT (US); Florian Solzbacher, Salt Lake City, UT (US); Brian Baker, Salt Lake City, UT (US)

(21) Appl. No.: 17/277,563

(22) PCT Filed: Sep. 19, 2019
(86) PCT No.: PCT/US19/51994

§ 371 Date: Mar. 18, 2021

Related U.S. Application Data
(60) Provisional application No. 62/733,335, filed on Sep. 19, 2018.

(51) Int. Cl. B81B 3/00; H05K 1/11; B81C 1/00

(52) U.S. Cl. CPC B81B 3/0021; H05K 1/115; B81B 2201/0264; B81B 2201/0214; B81C 1/00182

(57) ABSTRACT

A membrane based microelectronic device (200) can include a printed circuit board (202), a polymer film (210) laminated onto the circuit board, and one or more microelectromechanical components (208) integrated into the printed circuit board (202). At least a portion of the polymer film (210) forms a membrane element of the one or more microelectromechanical components (208).

### RELATED APPLICATION

This application claims priority to U.S. Provisional Application No. 62/733,335, filed Sep. 19, 2018, which is incorporated herein by reference.

### GOVERNMENT INTEREST

This invention was made with government support under Contract No. DE-SC0017168 awarded by U.S. Department of Energy. The government has certain rights in the invention.

### SUMMARY

A membrane based microelectronic device is disclosed that includes a flexible or rigid printed circuit board (PCB); a polymer film laminated onto the printed circuit board; and one or more microelectromechanical components integrated into the printed circuit board. At least a portion of the polymer film also forms a membrane element of the one or more microelectromechanical components. In some examples, the layer of conductive metal is embedded in the printed circuit board. The device further includes a layer of conductive metal, where the layer of conductive metal is electrically connected to the one or more microelectromechanical components.

In some non-limiting examples, the one or more microelectromechanical components include one or more of a strain gauge, a heating component, a variety of chemical, temperature, precipitation, pressure, flow sensors, and/or microfluidic devices such as, but not limited to, medical sensors, micropumps, microvalves, filters, reservoirs, and the like. In some example embodiments, the polymer film is a first polymer layer and the one or more microelectromechanical components are partially or fully encapsulated by one or more of the first polymer layer and a second polymer layer. The first polymer layer and the second polymer layer can optionally have different coefficients of thermal expansion. Furthermore, the printed circuit board can include one or more through vias.

A membrane based microelectronic device is disclosed that includes a printed circuit board, a conductive layer embedded in the printed circuit board, a first polymer film laminated onto the printed circuit board, one or more microelectromechanical components integrated into the printed circuit board and at least partially over the first polymer film, and a second polymer film over the first polymer film to form a membrane around the one or more microelectromechanical components.

A complimentary method of making a membrane based microelectronic device can comprise the steps of attaching a pre-fabricated polymer film to a printed circuit board. At least a portion of the attached pre-fabricated polymer film can be removed. One or more microelectromechanical components are also deposited such that the one or more microelectromechanical components are integrated into the printed circuit board. At least a portion of the polymer film forms a membrane element of the one or more microelectromechanical components.

In some examples, the method further includes encapsulating the one or more microelectromechanical components with another polymer layer. Removing at least a portion of the attached pre-fabricated polymer film can include using dry etching techniques to remove at least a portion of the polymer film layer. Dry etching techniques can create holes in the polymer film layer to allow contact between the printed circuit board and the one or more microelectromechanical components.

In some further examples, removing at least a portion of the attached pre-fabricated polymer film can include using photolithography to remove at least a portion of the polymer film layer. Furthermore, depositing one or more microelectromechanical components onto the printed circuit board can comprise using a suitable physical vapor deposition technique to deposit a film on the pre-fabricated polymer film. In some examples the physical vapor deposition can be sputtering. Similarly, the film can be metallic, polymer, ceramic, semiconductor, or other suitable material for making the corresponding intended device. A mask can be used to selectively deposit the film based on a pre-determined pattern. In some examples, the film is 100 nanometers thick. In some examples, the metallic film comprises aluminum and/or platinum.

Although a thickness of the pre-fabricated polymer film can vary considerably, as a general guideline the film can be less than about 400 μm. As a general guideline, the film thickness can range from about 200 nm to 500 μm. The pre-fabricated polymer film can be attached to the printed circuit board using a heat bonding process. The pre-fabricated polymer film can be attached to the printed circuit board using a lamination process. The one or more microelectromechanical components can include one or more of a strain gauge, a heating component, actuator, or a sensor

There has thus been outlined, rather broadly, the more important features of one or more embodiments so that the detailed description thereof that follows may be better understood, and so that the present contribution to the art may be better appreciated. Other features of the present invention will become clearer from the following detailed description of the invention, taken with the accompanying drawings and claims, or may be learned by the practice of the invention.

### BRIEF DESCRIPTION OF THE DRAWINGS

Features and advantages of example embodiments will be apparent from the detailed description which follows, taken in conjunction with the accompanying drawings, which together illustrate, by way of example, features; and, wherein:

FIGS. 1A through 1E illustrates a series of manufacturing steps for an example microelectromechanical systems (MEMS) device in accordance with an example embodiment.

FIG. 2 illustrates an example of a microelectromechanical system for metal oxide based gas sensing in accordance with some embodiments.

FIG. 3 illustrates an example of a microelectromechanical system for pressure sensing in accordance with some embodiments.

FIG. 4 illustrates an example of a microelectromechanical system for flow measurement (e.g. hot film anemometers) in accordance with some embodiments.

FIG. 5 illustrates an example of a microelectromechanical system for thermally activated micropumps in accordance with some embodiments.

FIG. 6 is a photograph showing patterning of a polymer film (KAPTON) using dry etching (RIE).

FIG. 7 illustrates deposition and patterning of platinum structures on the film of FIG. 6.

FIG. 8 illustrates an array of platinum microstructures formed as in FIG. 7.

FIG. 9 illustrates a sputter deposited aluminum pattern of contacts onto the array of FIG. 8.

FIG. 10 illustrates a patterned microheater structure formed directly on a PCB substrate.

FIG. 11 illustrates the patterned microheater structure of FIG. 10 subsequent to metallization and lift-off.

Reference will now be made to the exemplary embodiments illustrated, and specific language will be used herein to describe the same. It will nevertheless be understood that no limitation on scope is thereby intended.

These drawings are provided to illustrate various aspects of the invention and are not intended to be limiting of the scope in terms of dimensions, materials, configurations, arrangements or proportions unless otherwise limited by the claims.

### DETAILED DESCRIPTION

Before technology embodiments are described, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for describing particular examples or embodiments only and is not intended to be limiting. The same reference numerals in different drawings represent the same element. Numbers provided in flow charts and processes are provided for clarity in illustrating steps and operations and do not necessarily indicate a particular order or sequence.

Furthermore, the described features, structures, or characteristics can be combined in any suitable manner in one or more embodiments. In the following description, numerous specific details are provided, such as examples of layouts, distances, network examples, etc., to convey a thorough understanding of various technology embodiments. One skilled in the relevant art will recognize, however, that such detailed embodiments do not limit the overall technological concepts articulated herein, but are merely representative thereof.

As used in this written description, the singular forms “a,” “an” and “the” include express support for plural referents unless the context clearly dictates otherwise. Thus, for example, reference to “a” layer includes a plurality of such layers.

Reference throughout this specification to “an example” means that a particular feature, structure, or characteristic described in connection with the example is included in at least one technology embodiment. Thus, appearances of the phrases “in an example” or “in an embodiment” in various places throughout this specification are not necessarily all referring to the same embodiment.

As used herein, a plurality of items, structural elements, compositional elements, and/or materials can be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary. In addition, various embodiments and examples can be referred to herein along with alternatives for the various components thereof. It is understood that such embodiments, examples, and alternatives are not to be construed as de facto equivalents of one another, but are to be considered as separate and autonomous representations under the present disclosure.

Furthermore, the described features, structures, or characteristics can be combined in any suitable manner in one or more embodiments. In the following description, numerous specific details are provided, such as examples of layouts, distances, network examples, etc., to provide a thorough understanding of embodiments of the disclosed technology. One skilled in the relevant art will recognize, however, that the technology can be practiced without one or more of the specific details, or with other methods, components, layouts, etc. In other instances, well-known structures, materials, or operations may not be shown or described in detail to avoid obscuring aspects of the disclosure.

In this disclosure, “comprises,” “comprising,” “containing” and “having” and the like can have the meaning ascribed to them in U.S. Patent law and can mean “includes,” “including,” and the like, and are generally interpreted to be open ended terms. The terms “consisting of” or “consists of” are closed terms, and include only the components, structures, steps, or the like specifically listed in conjunction with such terms, as well as that which is in accordance with U.S. Patent law. “Consisting essentially of” or “consists essentially of” have the meaning generally ascribed to them by U.S. Patent law. In particular, such terms are generally closed terms, with the exception of allowing inclusion of additional items, materials, components, steps, or elements, that do not materially affect the basic and novel characteristics or function of the item(s) used in connection therewith. For example, trace elements present in a composition, but not affecting the composition's nature or characteristics would be permissible if present under the “consisting essentially of” language, even though not expressly recited in a list of items following such terminology. When using an open-ended term in this written description, like “comprising” or “including,” it is understood that direct support should be afforded also to “consisting essentially of” language as well as “consisting of” language as if stated explicitly and vice versa.

The terms “first,” “second,” “third,” “fourth,” and the like in the description and in the claims, if any, are used for distinguishing between similar elements and not necessarily for describing a particular sequential or chronological order. It is to be understood that any terms so used are interchangeable under appropriate circumstances such that the embodiments described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

As used herein, comparative terms such as “increased,” “decreased,” “better,” “worse,” “higher,” “lower,” “enhanced,” “minimized,” “maximized,” “increased,” “reduced,” and the like refer to a property of a device, component, function, or activity that is measurably different from other devices, components, or activities in a surrounding or adjacent area, in a single device or in multiple comparable devices, in a group or class, in multiple groups or classes, related or similar processes or functions, or as compared to the known state of the art. For example, an “increased” risk of corruption can be caused by a number of factors including location, fabrication process, etc.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases, depend on the specific context. However, generally speaking, the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint. However, it is to be understood that even when the term “about” is used in the present specification in connection with a specific numerical value, that support for the exact numerical value recited apart from the “about” terminology is also provided. Unless otherwise enunciated, the term “about” also generally connotes flexibility of less than 2%, and most often less than 1%, and in some cases less than 0.01%.

The term “coupled,” as used herein, is defined as directly or indirectly connected in an electrical or nonelectrical manner. “Directly coupled” items or objects are in physical contact and attached to one another. Objects or elements described herein as being “adjacent to” each other may be in physical contact with each other, in close proximity to each other, or in the same general region or area as each other, as appropriate for the context in which the phrase is used.

Numerical amounts and data may be expressed or presented herein in a range format. It is to be understood, that such a range format is used merely for convenience and brevity, and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 1.5, 2, 2.3, 3, 3.8, 4, 4.6, 5, and 5.1 individually.

This same principle applies to ranges reciting only one numerical value as a minimum or a maximum. Furthermore, such an interpretation should apply regardless of the breadth of the range or the characteristics being described.

### EXAMPLE EMBODIMENTS

An initial overview of technology embodiments is provided below and then specific technology embodiments are described in further detail later. This initial summary is intended to aid readers in understanding the technology more quickly but is not intended to identify key features or essential features of the technology nor is it intended to limit the scope of the claimed subject matter.

Micro-electromechanical systems (MEM systems) employ the technology of microscopic devices (including those with moving parts) to perform tasks. As technologies for creating MEM systems has improved, MEM systems have become very common in a plurality of different technology areas. For example, MEM systems can be employed in various technology areas, including but not limited to, inkjet printers, accelerometers, inertial measurement units (IMUs), displays, optical switches, energy harvesters, ultrasound transducers, etc. Generally, MEM systems are used for sensors and actuators on a nanometer to millimeter scale.

However, the process for manufacturing MEM systems is complicated and expensive, and as a result MEM systems most often must be produced in very large quantities to be profitable. Thus, the initial costs to begin manufacturing a MEM system can be prohibitive, especially for research or small business environments. Furthermore, with such large manufacturing costs creation of prototypes can be a challenge.

As disclosed herein, the costs and time needed to create a MEM system can be reduced by using a printed circuit board (PCB) to replace traditional substrates used for creating MEM systems. This PCB-MEMS technology replaces conventional substrates, which are currently used for microfabrication, with a polymer film laminated onto the printed circuit board (PCB). The polymer films as well as the PCB material can be vacuum process compatible, meaning that outgassing properties meet either the standards set by American Society for Testing and Materials (ASTM) E 595-77/84/90 or E 595-77/84/90.

In the disclosed technology, an application specific PCB can be coupled or directly coupled with a computing platform such as, but not limited to, a Particle Flux Analytics Inc. (PFA) computing platform (communications, firmware, hardware and operating system configuration). The PCB can include an application specific integrated circuit (ASIC). The PCB is designed according to a specified use case, dimensions and layout of the particular MEMS devices. A polymer film is subsequently laminated onto the PCB. The MEMS structures can be deposited and patterned onto the laminated film using conventional microfabrication technology. The micro-fabricated components are directly contacted to vias and/or pads of the underlying PCB. PCBs where vias, pads, traces, and even milled structures such as cavities, already exist on the board and can be ordered for a fraction of the price of commonly used unprocessed micromachining substrates.

The disclosed technology can significantly reduce the cost for the fabrication and assembly of MEMS by reducing the material costs and fabrication time and effort. The PCB-MEMS technology presents a cost effective alternative way of prototyping and developing new MEMS devices, making smaller batch sizes of MEMS much more economically feasible. In addition, the disclosed PCB-MEMS technology offers the advantage of simple routing and electrical contacting. This advantage eliminates expensive and time-consuming packaging steps such as wire bonding and also allows simple scaling of patterns up to large structure covered surfaces. The disclosed PCB-MEMS technology can allow the fabrication of MEMS devices for a fraction of the current cost, but also allows high density implementation of microsystems on very large scales. Because of its ability to fabricate cost effective devices in small and larger batches, this technology can lead to the development of a multitude of useful novel microsystems including, but not limited to, the large consumer electronics market (e.g. cell phone market, medical devices, automotive applications etc.) as well as more application specific markets, which were previously excluded due to lower production volumes.

In the disclosed technology, conventional MEMS substrates can be replaced with a polymer film laminated onto a printed circuit board, rather than more expensive substrates such as silicone, glass, ceramics, etc. This can reduce the cost and time for fabrication and assembly of MEMS devices, as well as prototyping.

As the MEMS market continues to expand as Internet of Things (IoT) and other smart devices continues to grow, improved techniques and fast and cheap MEMS production can become more desirable. The MEMS market is expected to particularly experience large growth in the areas of healthcare, environmental sensors and automobiles.

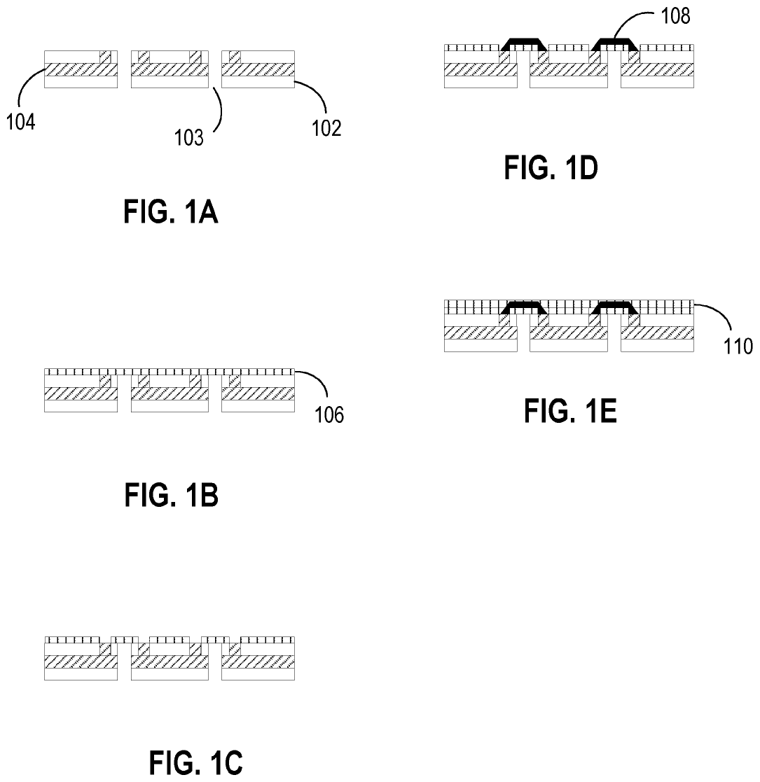

FIGS. 1A through 1E illustrates a series of manufacturing steps for an example MEMS device in accordance with an example embodiment. FIG. 1A illustrates the first step in an example process for manufacturing a MEMS device. In this example, the process begins with a printed circuit board (PCB) 102 with an embedded conductive layer 104. The PCB 102 with the embedded conductive layer 104 is an electronic circuit to which integrated circuits and other components can be attached. In other words, generally speaking, the PCB 102 is an electronic circuit consisting of thin strips of a conducting material, which have been etched from a layer fixed to a flat insulating sheet, and to which integrated circuits and other components are attached. The PCB 102 can mechanically support and electronically connect electronic components or electrical components using conducting tracks, pads and other features etched from one or more conductive sheets laminated onto and/or between sheet layers of a non-conductive material.

The PCB 102 can be rigid or flexible. In some examples, the embedded conductive layer 104 comprises a conductive metal such as copper, silver, aluminum, etc. Rigidity can depend on material composition and thickness. Regardless, as a general rule, rigid substrates can include, but are not limited to, phenolic paper, epoxy, glass/epoxy composites, polytetrafluoroethylene (TEFLON), aluminum oxide, ceramics, insulated metal substrates, and the like. Similarly, flexible substrates can include, but are not limited to, polyester, polyimides (e.g. KAPTON), polyimide copper clad laminates (e.g. PYRALUX), liquid crystal polymers (LCP), and the like. PCB substrate thickness can often vary depending on the specific application. However, as a general guideline, substrate thicknesses can range from 1 μm to 1 cm, and most often from 0.2 to 5 mm.

The PCB 102 also includes one or more through holes 103 that allow contact between the top and bottom of the PCB 102. The holes 103 can be in various sizes or shapes that allow contact between the top and bottom of the PCB 102. Shapes can vary from circular, oval, square, rectangular, triangular, or the like, although other shapes may be useful. Through holes can also vary in size but can generally range from 50 μm to 1 cm, and most often from 150 μm to 5 mm in diameter.

FIG. 1B illustrates another step in the example process for manufacturing a MEMS device. In this example, a polymer film 106 is adhered to the PCB 102. In some examples, the polymer film 106 is pre-fabricated and then cut to fit the PCB 102. The polymer film 106 is adhered using a heat bonding process (e.g., using a heat press). The heat bonding process can involve applying a certain temperature for a defined period of time, thereby adhering the polymer film 106 to the PCB 102. For example, a polymer film of KAPTON can be overlaid and subjected to a temperature of about 350° C. at a pressure of ca. 1.4 bar. Polymer type and thickness can affect temperature ranges and times based on polymer film manufacturer recommendations. Other film securing processes can also be used such as an adhesion layer (e.g. fluorinated ethylene propylene, or FEP), thermoplastics, or the like. In some examples, the polymer film 106 is laminated to the PCB 102. For example, by applying a certain amount of heat and pressure for a duration of time (depending on the material), the polymer film 106 is laminated to the PCB 102.

Non-limiting examples of suitable polymer films can include polyimides, polyamides epoxy, silicones, SU8, and the like. Film thicknesses can also vary depending on the intended application but generally ranges from about 200 nm to 300 μm and most often from 500 to 200 μm. In some examples, the polymer film 106 is a 30 micrometer thick KAPTON polymer film. In other examples, the polymer film 106 is made of another type of polymeric material, such as polyethylene, polypropylene, etc. Furthermore, one or more polymer films can be laminated to one another or stacked adjacent to one another to form a multi-layered polymer film. Any number of polymer films may be stacked or laminated in order to achieve desired flexibility, durability, insulation, or other properties.

FIG. 1C illustrates another step in the example process for manufacturing a MEMS device. In this example, one or more sections of the polymer film 106 are removed from the PCB 102. In some examples, the polymer film 106 is removed by a process of dry etching. In some examples, the dry etching is a process of selective etching of the polymer film 106 to create holes in accordance with a pattern (e.g., circular or other shaped) and allowing contact between the PCB 102 and an upper surface of the polymer film 106. Dry etching involves the removal of the sections of polymer film 106 by exposing the sections to a bombardment of ions (e.g. a plasma of reactive gases such as fluorocarbons, oxygen, chlorine, boron trichloride; sometimes with addition of nitrogen, argon, helium and other gases) that dislodge the sections of the polymer film 106. One example of dry etching is reactive-ion etching.

Other non-limiting processes to remove the sections of the polymer film 106 can include laser ablation, wet etching, dry etching, and the like. Furthermore, the polymer film can be patterned using machining, dicing, or using a knife plotter, for example. Laser ablation can be used to remove the sections of the polymer film 106 by irradiating the sections with a laser beam. At a target laser flux, the sections of the polymer film 106 are heated by absorbed laser energy and evaporate or sublimate. Similarly, plasma etching can be used to remove the sections of the polymer film 106 by generating (in pulses) a high-speed stream of glow discharge (plasma) of an appropriate gas mixture.

FIG. 1D illustrates another step in the example process for manufacturing a MEMS device. In this example, one or more microelectromechanical components 108 can be added to the PCB 102 at least partially over the polymer film 104. In some examples, the process includes using photolithography to prepare the PCB 102 for depositing of microelectromechanical components 108. Photolithography is a process that uses light to transfer a geometric pattern from a photomask (or optical mask) to a photosensitive chemical photoresist of the PCB 102, which then allows the microelectromechanical components 108 to be deposited on the PCB 102. In some examples, the one or more microelectromechanical components 108 include, but are not limited to, a heater, a strain gauge, a sensor (e.g. MOX gas sensors), an actuator, micro-optical components, micro-fluidic components, and so on. Of particular interest are sensing elements having a relatively dense distribution across a larger surface area. For example, densities of greater than about 5 to about 10,000 per cm², and in some cases from about 100 to about 2,000 per cm².

In some examples, the process includes using any suitable deposition technique to deposit the polymer film 104 or the microelectromechanical components 108. The deposition techniques are used to deposit the polymer film 104 and/or the microelectromechanical components 108 typically having a thickness from one micrometer to about 100 micrometers. Non-limiting examples of deposition techniques include physical vapor deposition, chemical vapor deposition (e.g., low pressure chemical vapor deposition or plasma-enhanced chemical vapor deposition), sputter deposition, and the like.

In one example, a sputtering technique can be used to deposit a layer of conductive material (e.g., metal) to form the one or more microelectromechanical components 108. In some examples, the deposited material is platinum or aluminum, although non-metal materials can also be deposited such as, but not limited to, polymers, semiconductors, insulators, dielectrics, and the like.

FIG. 1E illustrates another step in the example process for manufacturing a MEMS device. In this example, an additional layer of polymer film 110 (or a second polymer film) is deposited or laminated to protect the one or more microelectromechanical components 108 (e.g., fabricated microstructures) from potential damages from humidity, mechanical damage, and corrosion. The additional layer of polymer film 110 can be of a same or different polymeric material as compared to the polymer film 106. Further, the additional layer of polymer film 110 can be of a same or different thickness as compared to the polymer film 106. In some examples, the additional layer of polymer film 110 is added using the polymer film lamination process. In some examples, the additional layer of polymer film 110 can be deposited by chemical vapor deposition (e.g. parylene-C), spin-coating (e.g. polyimide), silicones, epoxy, and so on. In some examples, the one or more microelectromechanical components 108 are connected to the PCB 102. In some examples, the connections can be made using soldered wires. Alternatively, electrical contacting can be provided by techniques such as, but not limited to, flip-chip bonding, reflow soldering, spring pins, wire bonding, and the like.

In one example, the MEMS device is a membrane based MEMS device, as the one or more microelectromechanical components 108 are sandwiched between the polymer film 106 and the additional layer of polymer film 110. In other words, the polymer film 106 and the additional layer of polymer film 110 forms a membrane element that partially or fully surrounds or encloses or encapsulates the one or more microelectromechanical components 108.

Typically, MEMS devices are formed using complex and expensive lithographic techniques on expensive silicon, glass and/or ceramic substrates. Here, lower-cost PCB can be used as a substrate to form the MEMS devices, and a pre-formed polymer film is laminated onto a PCB surface. In particular, the PCB can be used as a substrate to form membrane based MEMS devices, such as heaters, sensors, etc. In this case, the polymer film is not CVD, PVD or other formed onto the surface. Rather, a pre-existing film (e.g. FEP) is cut into shape and laminated onto the PCB surface. The polymer film can then be patterned, and then a MEM device formed in the polymer. Alternatively, the MEMS device(s) can first be formed in the film, and then subsequently laminated onto the PCB surface. Thus, MEMS devices can be built into a pre-existing polymer film either before or after laminating such a film onto a substrate, such as a PCB.

The MEMS device(s) can then be optionally integrated into a larger system or used as a stand-alone device.

In some examples, the disclosed PCB MEMS technology can be used for the fabrication of high density micro-heater arrays for precipitation measurement. Micro-patterned platinum heaters can encapsulated between two polymer layers which form a membrane element. The arrays of individually and thermally decoupled heaters detects the cooling signatures for mass, frequency, and microstructure of individual snow and rain particles.

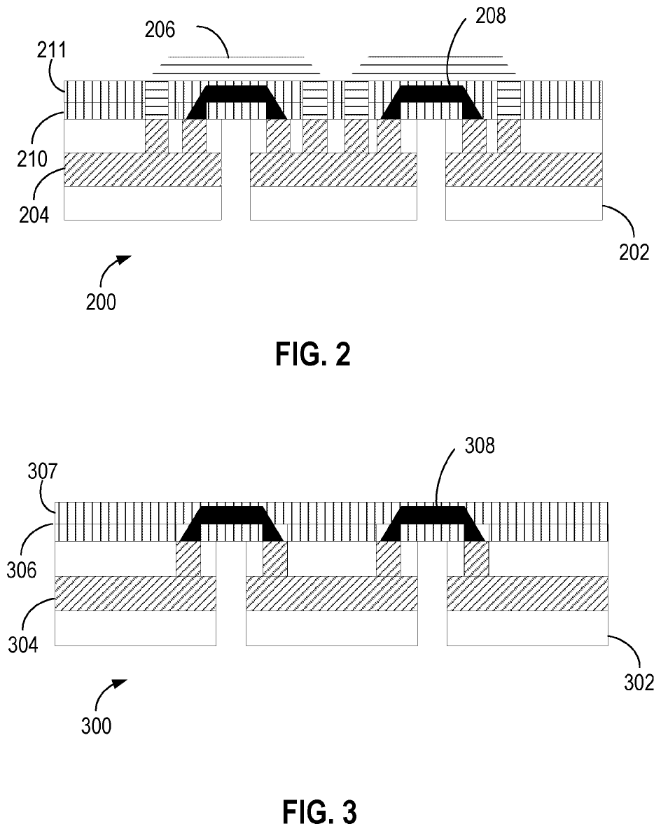

FIG. 2 illustrates an example of a microelectromechanical system 200 in accordance with some embodiments. In this example, the microelectromechanical system includes a micro-heater array. In some examples, the micro-heater array can be used for gas sensing applications. In this example, the microelectromechanical system 200 includes a PCB 202, a conductive layer 204, one or more polymer film layers 210, 211, one or more heater components 208, and a metal oxide (MOX) layer 206.

In some examples, the heater components 208 (which in this example are micro-patterned platinum heaters) are encapsulated between two polymer layers (a first polymer layer 210 below the heater component 208 and a second polymer layer 211 above the heater component 208). This membrane structure of the two polymer layers enclosing or encapsulating the heater component 208 reduces the thermal mass surrounding the heater component 208 and hence, the required heating power. MOX gas sensors typically operate with MOX surfaces at temperatures of several hundred degrees Celsius. For the fabrication of a gas sensor array, the MOX layers 206 are deposited and patterned on top of the second polymer layer 211 above the heater components 208. By contacting the MOX 206 to vias in the same fashion as the micro-heater components 208, the presented PCB MEMS technology can be used for the fabrication of gas sensors (e.g., FIG. 1A-1E). With the use of different MOX types, high density gas sensing arrays can be realized, which are sensitive to several gas types and which are able discriminate between them.

FIG. 3 illustrates an example of a microelectromechanical system 300 in accordance with some embodiments. In this example, the microelectromechanical system 300 includes a strain gauge. In this example, the strain gauge can be used to measure pressure difference. In this example, the microelectromechanical system 300 includes a PCB 302, a conductive layer 304, one or more polymer film layers 306, 307, and one or more strain gauges 308.

In some examples, the deflection of membrane structures resulting from a pressure difference (e.g., a first pressure (p1) does not equal a second pressure (p2) of the membrane element) is the basic principle for the majority of micro-machined pressure sensors. The presented PCB MEMS membrane structures offer a platform for low cost pressure sensors. Strain gauges 308 are deposited and patterned between the two polymer layers 306, 307 forming the membrane element. Depending on the deflection of the membrane as a result of the pressure difference for the membrane element, the strain gauge changes or varies resistance in response.

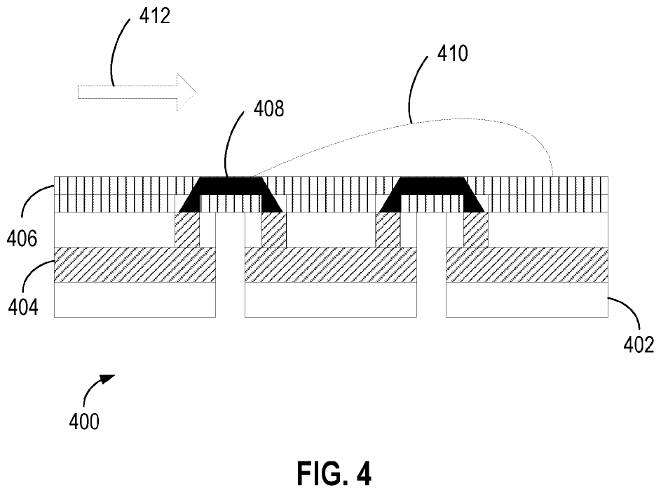

FIG. 4 illustrates an example of a microelectromechanical system 400 in accordance with some embodiments. In this example, the microelectromechanical system 400 includes a heater and/or a temperature sensors. In this example, the microelectromechanical system 400 includes a PCB 402, a conductive layer 404, one or more polymer film layers 406, and one or more heaters and/or temperature sensors 408. In some examples, calorimetric hot film anemometers consist of a heating element 408 and at least one thermal sensor 408 upstream and one downstream of the fluid flow. In some examples, platinum layers can act both as micro-heaters and thermal sensors 408. Micro-patterned platinum heaters 408 are therefore encapsulated between two polymer layers 406. The membrane structure reduces the thermal mass surrounding the heater 408 and hence, the required heating power. A distortion of a thermal profile surrounding the heating element by the fluid flow 410 and flow direction 412 can be detected by the thermal sensors 408.

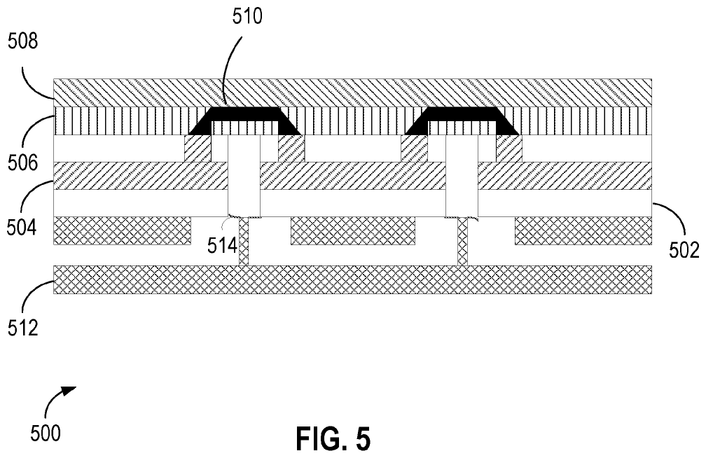

FIG. 5 illustrates an example of a microelectromechanical system 500 in accordance with some embodiments. In this example, the microelectromechanical system 500 includes a heater component. In this example, the microelectromechanical system 500 includes a PCB 502, a conductive layer 504, a first polymer film layer 506, a second polymer film layer 508, and one or more heaters 510.

In these examples, micro-patterned platinum heaters 508 are encapsulated between two different polymer layers, such as the first polymer film layer 506 and the second polymer film layer 508. Further, the first polymer film layer 506 can have a different coefficient of thermal expansion (CTE) as compared to the second polymer film layer 508. The CTE is a material property that is indicative of an extent to which a material expands due to heating. Due to the different CTE values of the polymer layers 506 and 508, the micro-heaters 508 can induce a deflection of a membrane element 514. Hence, the PCB MEMS technology can act as array of independent micro-pumps for an underlying microfluidic device 512.

### Example 1

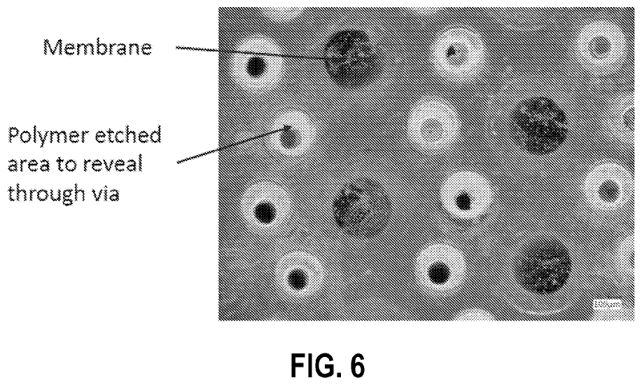

FIG. 6 is a photograph showing patterning of a polymer film (KAPTON) using dry etching (RIE). In this case, selective etching of 30 μm thick polymer film in plasma was used to create circular holes allowing contacting between PCB and polymer film upper surface. Although circular holes were formed, any other suitable shape can be formed depending on the etch process chosen, such as square, rectangular, elliptic, etc.

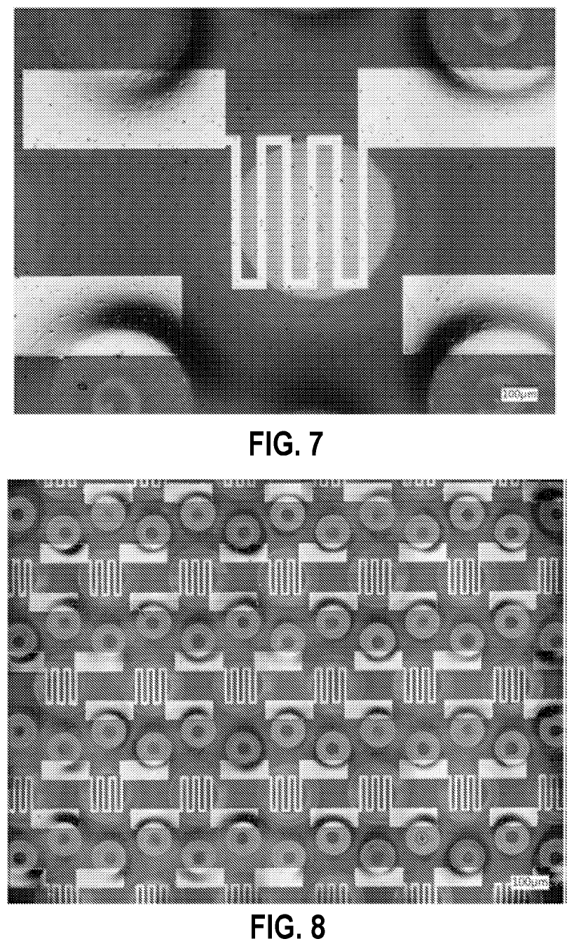

FIG. 7 illustrates a deposition and patterning of metal structures. Specifically, a 100 nm thick platinum film was sputtered onto the polymer coated PCB substrate. Generally, there would be no limitations on the metal thickness or material which could be deposited. Similarly, FIG. 8 illustrates an array of platinum microstructures on membrane elements having contacts on vias.

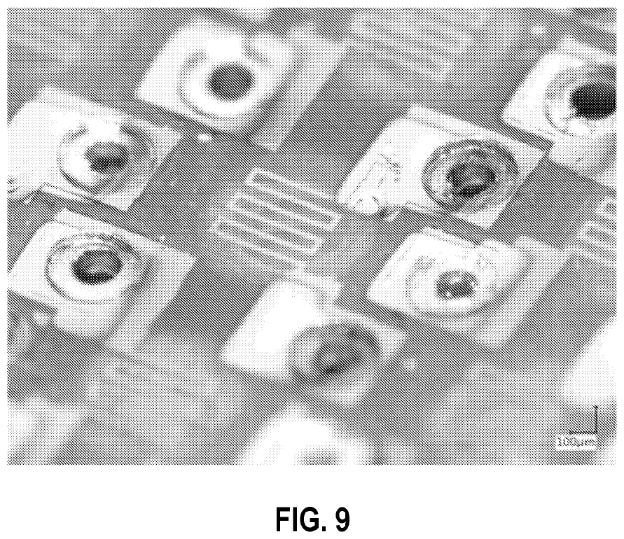

FIG. 9 illustrates a further step in patterning metal structures by deposition of an electrical contact pattern. Specifically, an 800 nm thick aluminum film was deposited via sputtering using a shadow mask to produce electric contact between the platinum structures of FIG. 8 and the underlying through vias. This provides a reliable and robust electric connection across multiple layers or levels of polymer film or PCB layers. Additional levels could be used for additional sensing and/or actuating elements, could be used for bond pads, circuitry in general, insulating and encapsulating layers, additional mechanical reinforcement on specific areas, or the like. This approach can also be applied using photolithography, e-beam lithography, or other processes.

### Example 2

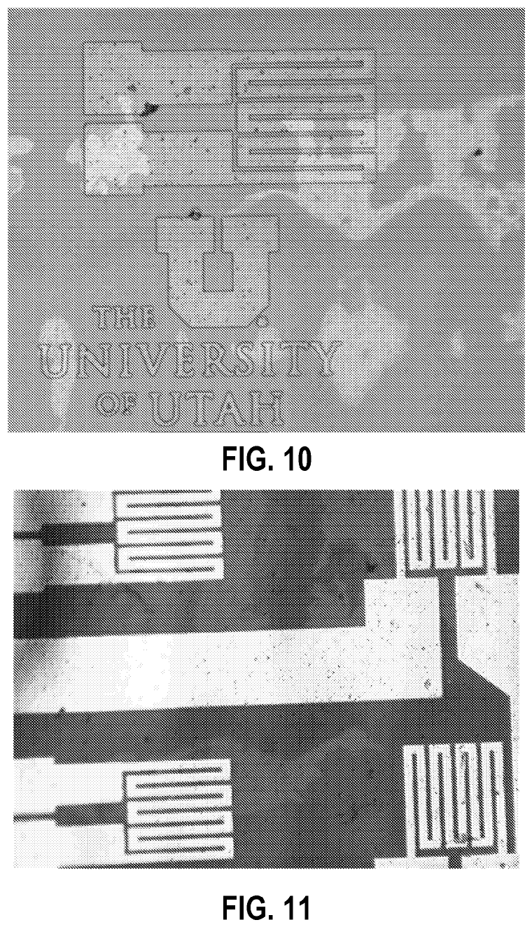

FIG. 10 illustrates a patterned microheater structure formed via lithography (spincoating AZ 9260, exposure, developing) carried out on polyimide films laminated onto a PCB substrate.

FIG. 11 illustrates the microheater structures subsequent to metallization and lift-off.

The foregoing detailed description describes the invention with reference to specific exemplary embodiments. However, it will be appreciated that various modifications and changes can be made without departing from the scope of the present invention as set forth in the appended claims. The detailed description and accompanying drawings are to be regarded as merely illustrative, rather than as restrictive, and all such modifications or changes, if any, are intended to fall within the scope of the present invention as described and set forth herein.

What is claimed is:

1. A membrane based microelectronic device comprising:
a rigid or flexible printed circuit board;
a polymer film laminated onto the printed circuit board; and
one or more microelectromechanical components integrated into the printed circuit board, wherein at least a portion of the polymer film forms a membrane element of the one or more microelectromechanical components.

2. The device of claim 1, further comprising:
a layer of conductive metal, the layer of conductive metal electrically connected to the one or more microelectromechanical components.

3. The device of claim 1, wherein the layer of conductive metal is embedded in the printed circuit board.

4. The device of claim 1, wherein the one or more microelectromechanical components is one of: a strain gauge, a heating component, or a sensor.

5. The device of claim 1, wherein the polymer film is a first polymer layer, and the one or more microelectromechanical components are partially or fully encapsulated by one or more of the first polymer layer and a second polymer layer.

6. The device of claim 5, wherein the first polymer layer and the second polymer layer have different coefficients of thermal expansion.

7. The device of claim 1, further comprising at least one additional polymer film laminated on the polymer film to form a multi-layered composite polymer film.

8. The device of claim 1, wherein the printed circuit board includes one or more through vias.

9. A method of making a membrane based microelectronic device, the method comprising:
attaching a pre-fabricated polymer film to a printed circuit board;
removing at least a portion of the attached pre-fabricated polymer film; and
depositing one or more microelectromechanical components such that the one or more microelectromechanical components are integrated into the printed circuit board, and wherein a portion of the polymer film forms a membrane element of the one or more microelectromechanical components.

10. The method of claim 9, further comprising:
encapsulating the one or more microelectromechanical components with another polymer layer.

11. The method of claim 9, wherein removing at least a portion of the attached pre-fabricated polymer film includes using dry etching techniques to remove at least a portion of the polymer film layer.

12. The method of claim 11, wherein the dry etching techniques create holes in the polymer film layer to allow contact between the printed circuit board and the one or more microelectromechanical components.

13. The method of claim 9, wherein removing at least a portion of the attached pre-fabricated polymer film includes using photolithography to remove at least a portion of the polymer film layer.

14. The method of claim 9, wherein depositing one or more microelectromechanical components onto the printed circuit board comprises using a sputtering technique to deposit a metallic film on the pre-fabricated polymer film.

15. The method of claim 14, wherein the metallic film is 100 nanometers thick.

16. The method of claim 14, further comprising using a mask to selectively deposit the metallic film based on a pre-determined pattern.

17. The method of claim 14, wherein the metallic film comprises aluminum.

18. The method of claim 14, wherein the metallic film comprises platinum.

19. The method of claim 9, wherein the pre-fabricated polymer film is less than 400 μm thick.

20. The method of claim 9, wherein the pre-fabricated polymer film is attached to the printed circuit board using a heating bonding process.

21. The method of claim 9, wherein the pre-fabricated polymer film is attached to the printed circuit board using a lamination process.

22. The method of claim 9, wherein the one or more microelectromechanical components is one of: a strain gauge, a heating component or a sensor.
